(19) United States
(12) Patent Application Publication
(10) Pub. No.: US 2011/0299164 A1
(43) Pub. Date: Dec. 8, 2011

(54) METHOD AND DEVICE FOR THE PRODUCTION OF A STRUCTURED OBJECT, AND STRUCTURED OBJECT

(75) Inventors: Ralf Biertumpeel, Mainz-Kastel (DE); Volker Wittmer, Mainz (DE); Charles Bernheim, Mainz (DE)

(73) Assignee: SCHOTT AG, Mainz (DE)

(21) Appl. No.: 13/058,577

(22) PCT Filed: Aug. 13, 2009
(86) PCT No.: PCT/EP2009/005873

§ 371 Date: Aug. 30, 2011

(30) Foreign Application Priority Data
Aug. 13, 2008 (DE) 10 2008 038 910.2

(51) Int. Cl. G02B 5/18; B32B 3/00; B29C 59/02; B29D 11/00; H01L 21/306

(52) U.S. Cl. 359/558; 216/24; 156/345.51; 425/385; 428/141

(57) ABSTRACT

The invention relates to a method for the production of a structured object, particularly an optical clement having a structure on an optically effective non-planar surface, preferably for structuring a non-planar surface of an object, and to objects produced according to the method. which comprises providing a base body, particularly having at least one non-planar surface, producing a structure, particularly on the at least one non-planar surface of the object, which comprises structuring a sacrificial layer, transferring the structure from the sacrificial layer onto a surface, wherein the surface is a surface of the base body, particularly a non-planar surface of the base body, or a surface on at least one further body which can be attached to the base body, wherein the thickness of the sacrificial layer can be at least reduced or changed during the transferring of the structure of the sacrificial layer onto the surface, thus structuring the surface.

The invention concerns a method and a device for producing a structured object, especially for structuring a nonplanar surface of an object, as well as the structured object thus produced.

With increasing storage capacity and local storage density of present-day data carriers, for example, the data carriers used in compact disc or blu-ray disc recording techniques, increased requirements with respect to optical imaging properties are being placed on both the recording process and the playback process. However, this considerably increases requirements on precision, including especially in the production of the optical elements used for recording and playback.

Optical elements of this type often also comprise microoptical elements that have Fresnel lens structures arranged on the surface of a transparent body.

In the production of these elements in large production numbers, preferably stamping or pressing methods are used, especially blank pressing methods with high precision.

Plastics have customarily been used for this purpose, especially polymers that can be structured at relatively moderate temperatures.

Furthermore, U.S. Pat. No. 5,436,764 A describes a method for press molding a microoptical glass element. In this method, structures are introduced into the planar surface of a glass body.

DE 10 2006 059 775 describes a tantalum-coated die for pressing optical components that makes it possible to introduce refractive structures, especially in glass bodies.

However, with the growing requirements on optical precision, especially resolving power, there is a need for optical systems that have Fresnel-lens-like or diffractive structures on nonplanar surfaces as well, for example, on refractive optical components.

However, since press molds with the high precision required here have generally been produced by lithographic methods, which, however, provide the necessary resolution essentially only in a planar image plane, the production of diffractive structures on nonplanar surfaces was extremely difficult or impossible.

The objective of the invention is to make available a method and a device for producing a structured object, with which it is also possible to structure a nonplanar surface of an object, so that it is possible, for example, to create optical systems, especially for use at relatively short wavelengths, such as blue light.

This objective is achieved with a method with the features of claim 1 and with a device with the features of claim 30.

With this method and preferably with this device as well, it is possible to produce as structured bodies both dies and optical components directly and with high precision.

Where optical elements are concerned, this method makes it possible to achieve an edge steepness of the Fresnel structures of greater than 70° relative to the principal plane of the optical element. For many materials, it was even possible to achieve edge steepnesses of almost 90° relative to the principal plane of the optical element, which means it was possible to produce a surface lying almost in the pressing direction.

Optical systems with optical components produced in accordance with the invention achieve, for example, numeric aperture (NA) values of greater than 0.6.

The invention comprises a method for producing a structured object and especially for structuring a nonplanar surface of an object, which includes the preparation of a base body, especially one with at least one nonplanar surface; the production of a structure, especially on the one or more nonplanar surfaces of the object; the structuring of a sacrificial layer; and the transfer of the structure of the sacrificial layer to the surface, where the surface is a surface of the base body, especially a nonplanar surface of the base body or a surface of at least one additional body that can be applied to the base body, such that during the transfer of the structure of the sacrificial layer to the surface, the thickness of the sacrificial layer is at least reduced or changed, thereby structuring the surface.

The above method makes it possible to transfer the structure and especially to transfer the lateral structure and to transfer a similar vertical structure.

In a preferred embodiment, the sacrificial layer is completely consumed.

In general, it is advantageous if the structure is transferred by dry etching, especially reactive ion etching.

In an alternative or additional refinement of the method, the structure can be transferred by wet-chemical etching, especially directional etching along preferred crystal directions.

Preferably, the structured body can be a stamping or pressing mold, especially a blank pressing mold, for producing an optical element, especially for producing an optical element that consists of glass or glass ceramic and that preferably has diffractive and/or refractive structures.

In this method, at least parts of the base body can be structured by grinding, polishing or lapping its surface, and in the process, for example, a base form can be obtained that has a high degree of surface precision with a (mean, maximum) deviation of better than 2 μm relative to the nominal form.

In this method or, alternatively, with additional production steps, at least parts of the surface of the base body can be formed spherically, aspherically, or freely.

The base body can consist partly or completely of a material selected from the group comprising ceramic materials and crystalline materials.

Advantageously, the ceramic materials can comprise tungsten carbides, aluminum carbides, silicon carbides, titanium carbides, aluminum oxides, zirconium oxides, silicon nitrides, aluminum titanates, and/or aluminum sintered materials, and/or mixtures of these materials, especially as sintered materials, including especially powder metallurgy materials.

The crystalline materials preferably comprise silicon or sapphire.

In an advantageous further refinement of the method, the base body is coated with an antiadhesive coating.

In this connection, the antiadhesive coating can consist of a platinum-gold alloy, especially Pt₅Au, and/or alloys that contain platinum, iridium and rhodium. Furthermore, carbon coatings, preferably DLC (diamond-like carbon), are also suitable as antiadhesive coatings.

In an especially preferred embodiment, the base body is structured, and then the antiadhesive coating is applied.

Alternatively or additionally to a preceding structuring of the base body, the antiadhesive coating can be applied and then structured, including especially with the use of a, preferably additional, sacrificial layer.

Advantageously, the sacrificial layer can comprise metals and/or metallic alloys, especially nickel or a nickel-boron, nickel-phosphorus-boron, or nickel-phosphorus alloy.

Very high precision, especially with deviations from the desired form of less than 0.5 μm, can be achieved if the sacrificial layer is structured by means of a removal technique, especially by lithography, especially x-ray lithography, laser ablation and/or single crystal diamond machining, especially single crystal diamond turning.

In an alternative refinement or in addition to a metallic layer or a metallic layer component, the sacrificial layer can also or alternatively comprise a dielectric; in particular, it can comprise a resist, preferably a photoresist, a polymerizable substance, especially a photopolymerizable substance, and/or also a glass or a ceramic produced by a sol-gel process, such as zirconium oxide.

Advantageously, the sacrificial layer can be structured by an application technique, especially laser polymerization, printing, especially three-dimensional printing, preferably with nanoparticle constituents, especially with nanoparticle metal constituents, plastic constituents and/or ceramic constituents.

Furthermore, there is the possibility of structuring the sacrificial layer with both deposition and removal techniques in order, for example, to increase the production rate in this way. For example, a thick photoresist can be applied structured with thickness on the order of up to 50 μm, and then the photoresist can be finished in its thickness with a precision of, say, contour errors better than 2 μm by means of single crystal diamond grinding.

For the highest precision, it is advantageous if the removal rate of the sacrificial layer is greater than or equal to the removal rate of the base body or the additional body, since the structure of the structured body then does not exceed the tolerances of the sacrificial layer. For example, if the removal rate of the sacrificial layer is ten times greater than the removal rate of the base body, then, to be sure, on average, from the thickness only one tenth of the structural depth of the sacrificial layer is transferred into the base body, but the surface errors or deviations are also present in the structured body only to the extent of one tenth.

If, however, the removal rate of the sacrificial layer is less than the removal rate of the base body or of the additional body, deeper structures can be introduced into the base body, and greater attention must be given to the precision of the surface of the structured sacrificial layer. An alternative that is inexpensive and favorable from the standpoint of production engineering is realized is the additional body is, for example, a film.

It is advantageous if the additional body is a film of a polymeric material that consists especially of polycarbonate, polyethylene, and/or methyl methacrylate.

The structured body or especially the structured optical component can comprise Fresnel structures, diffractive optical structures and/or refractive optical structures.

In a preferred alternative embodiment, the structured body can also contain microfluidic structures.

The device of the invention for producing a structured body preferably comprises a holding fixture for holding the base body and at least a first and a second device for structuring a surface.

In this device, it is advantageous if the first contouring or structuring device comprises a grinding spindle, a polishing spindle, a turning machine (single crystal diamond turning machine), a milling machine (single crystal diamond milling machine) and/or a laser structuring device, especially a laser ablation device with an ablating laser and/or with an image setting laser, which is suitable especially for the image setting of photoresists or photopolymers.

In this device, it is advantageous if the second structuring device, especially for fine structuring, comprises a lithographic structuring device, especially a photolithographic structuring device, a galvanic structuring device, a turning machine for structuring (preferably a single crystal diamond turning machine), a milling machine for structuring (preferably a single crystal diamond milling machine) and/or a stamping device.

Furthermore, in this device, the holding fixture for holding the base body is suited in an advantageous way for holding the base body during the machining by the first structuring device and by the second structuring device, especially without new mounting of the base body and essentially without changed positioning.

For increased requirements on precision, it is advantageous if, in a first step, a nonplanar optically active contour is introduced into the base body or additional body, and at the same time at least two alignment marks or alignment areas are positioned in the regions that are not optically active.

These alignment marks can be realized, especially as reflecting surfaces that are planar, convex or concave. In this way, the position of the optically active contour relative to the alignment areas or marks is clearly established. The position of the optically active contour in the device can thus be exactly adjusted down to the nanometer range.

Moreover, the optical alignment area or alignment mark can also be positioned within the optically active area and in this way can be helpful, for example, in the centering and, additionally or alternatively, in the axial adjustment of an optical system, or can make this possible for the first time with the necessary precision.

This means that the alignment area is part of an optical system on the device or machining machine, so that a slight misalignment of a few nanometers already produces a detectable change in the optical performance of the system. In a simple case, the optical system for each alignment area consists of a collimated laser, the reflecting alignment area and a detector unit.

With this alignment system, it is possible to produce an optically active surface, take it from the machining machine, and then coat it with a sacrificial layer or antiadhesive coating. The coated body can then be placed back in the same or a different piece of machining equipment and be exactly aligned by means of the alignment marks to introduce a fine structure into the sacrificial layer or antiadhesive coating.

The invention is described in greater detail below on the basis of preferred embodiments and with reference to the accompanying drawings.

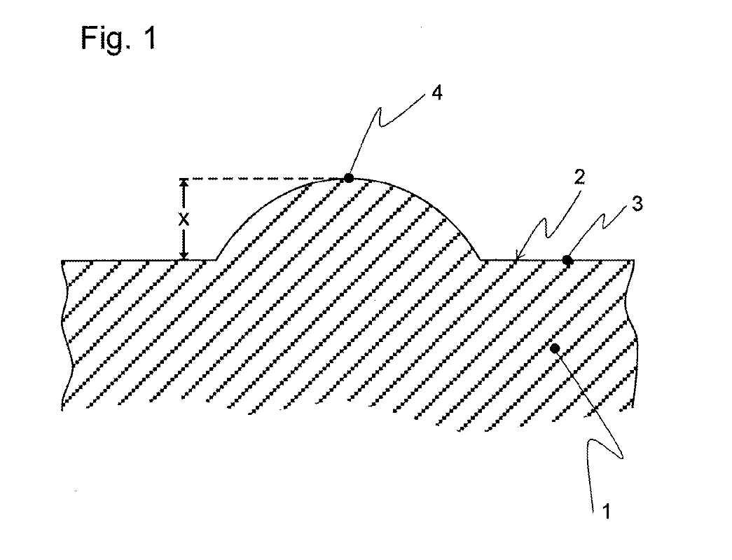

FIG. 1 shows a partial cross-sectional view of a first, but only exemplary, embodiment of an object to be structured, which has an at least regionally nonplanar surface (a convex surface in the present embodiment).

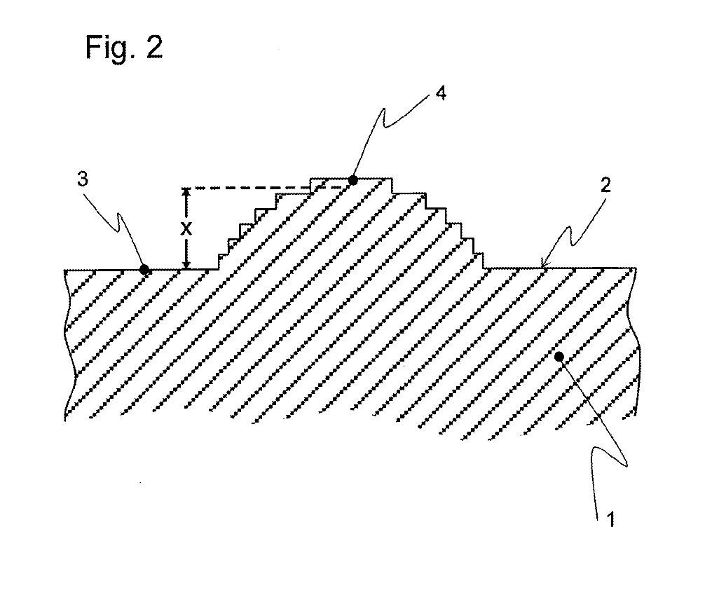

FIG. 2 shows a partial cross-sectional view of the same first embodiment of an object illustrated in FIG. 1 with a structure introduced in accordance with the invention in the at least regionally nonplanar surface.

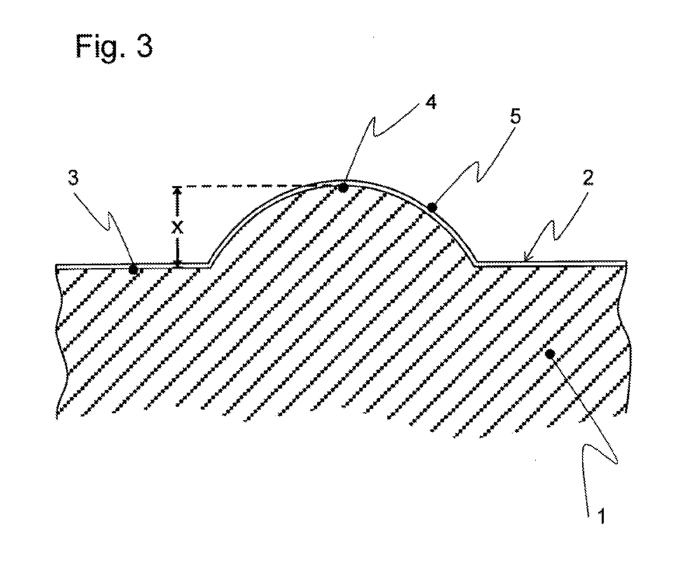

FIG. 3 shows a partial cross-sectional view of the same first embodiment of an object illustrated in FIGS. 1 and 2 with a sacrificial layer applied on the at least regionally nonplanar surface.

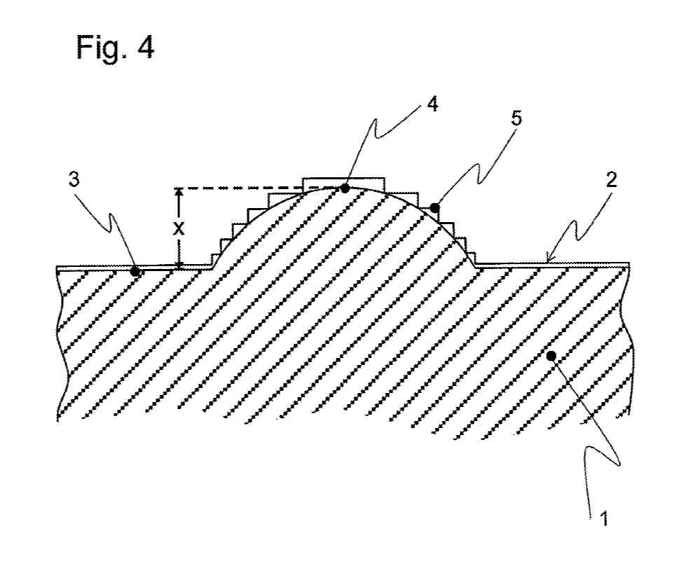

FIG. 4 shows a partial cross-sectional view of the same first embodiment of an object illustrated in FIGS. 1 and 2 with a sacrificial layer applied on the at least regionally nonplanar surface, into which a structure has been introduced, or a structured sacrificial layer has been deposited.

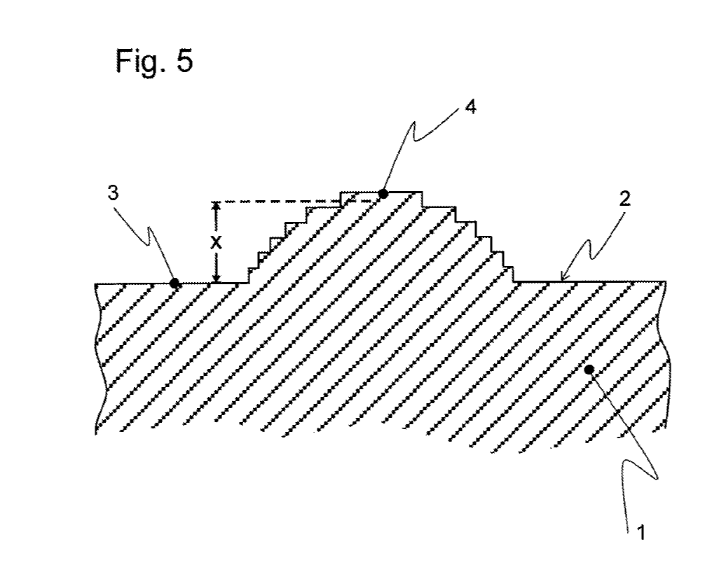

FIG. 5 shows a partial cross-sectional view of the same first embodiment of an object illustrated in FIG. 4, in which the structure that was introduced into the sacrificial layer has been transferred to the object.

FIG. 6 shows a partial cross-sectional view of the same first embodiment of a structured object illustrated in FIG. 5, in which an antiadhesive coating has been applied to at least part of the structure that was transferred to the object.

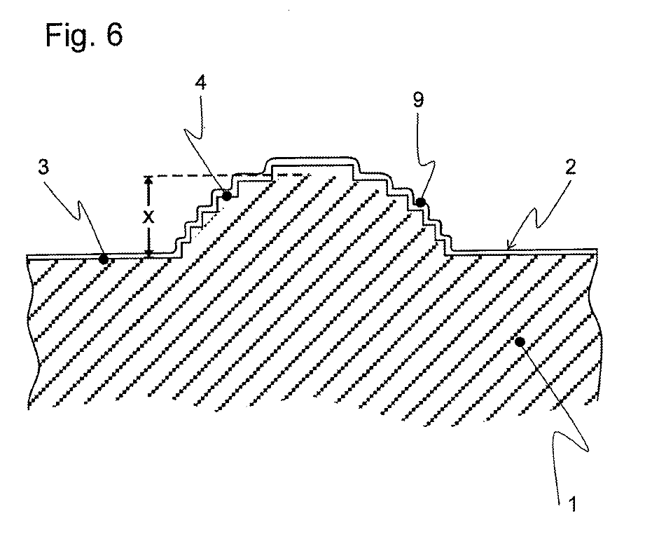

FIG. 7 shows a partial cross-sectional view of the same first embodiment of a structured object illustrated in FIG. 6, in which at least part of the antiadhesive coating was structured.

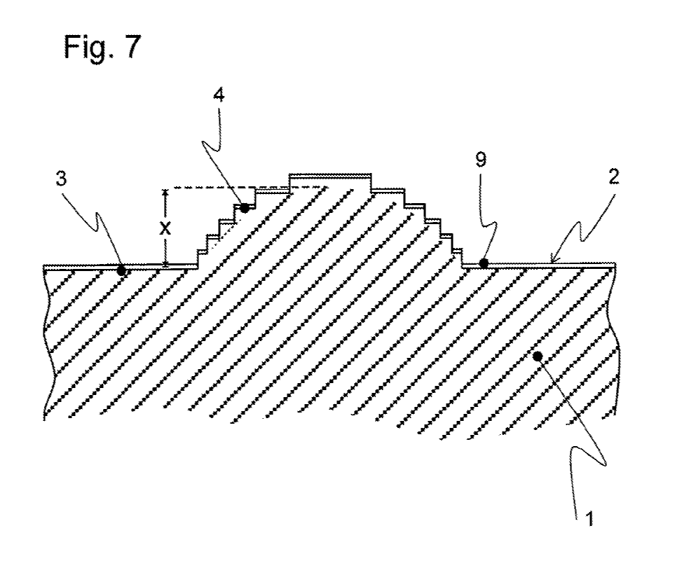

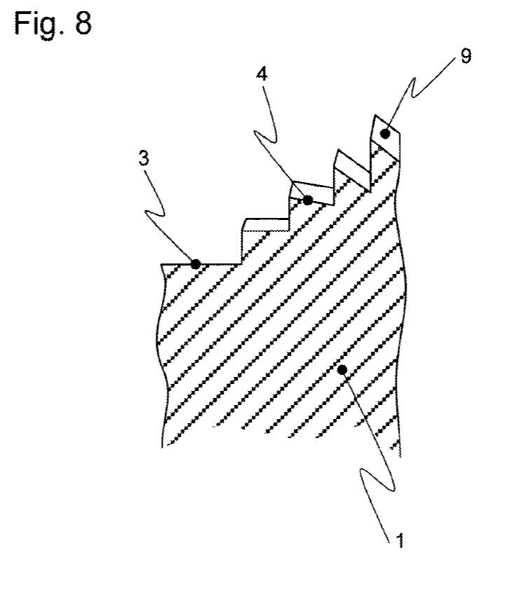

FIG. 8 shows a partial cross-sectional view of an enlarged segment of the same embodiment of a structured object illustrated in FIG. 7, in which at least part of the antiadhesive coating was structured.

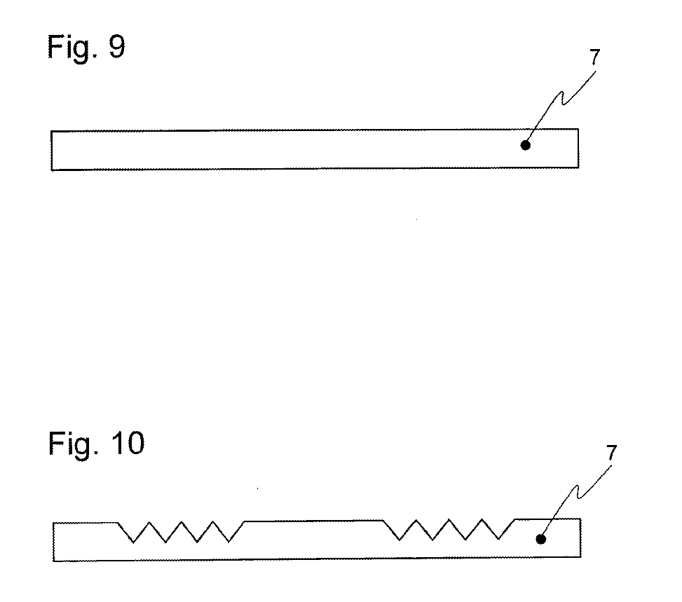

FIG. 9 shows a cross-sectional view of a first embodiment of an additional body, which can be structured and applied to a base body in accordance with the invention.

FIG. 10 shows a cross-sectional view of the additional body illustrated in FIG. 9, which has been structured in accordance with the invention.

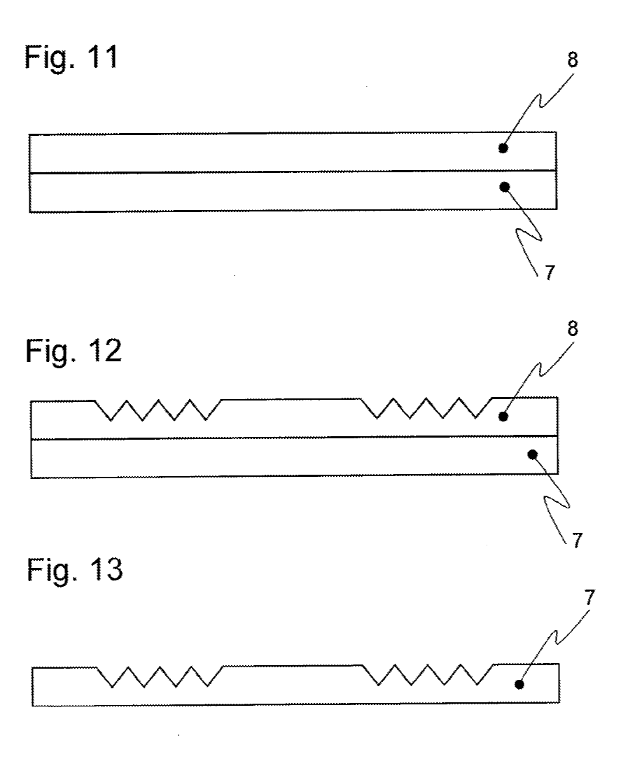

FIG. 11 shows a cross-sectional view of an alternative embodiment of an additional body, which can be structured and applied to a base body in accordance with the invention and on which a sacrificial layer has been applied.

FIG. 12 shows a cross-sectional view of the alternative embodiment of the additional body illustrated in FIG. 11, on which the sacrificial layer applied to it has been structured.

FIG. 13 shows a cross-sectional view of the alternative embodiment of the additional body illustrated in FIG. 12, on which the structure of the sacrificial layer applied to it has been transferred to the additional body.

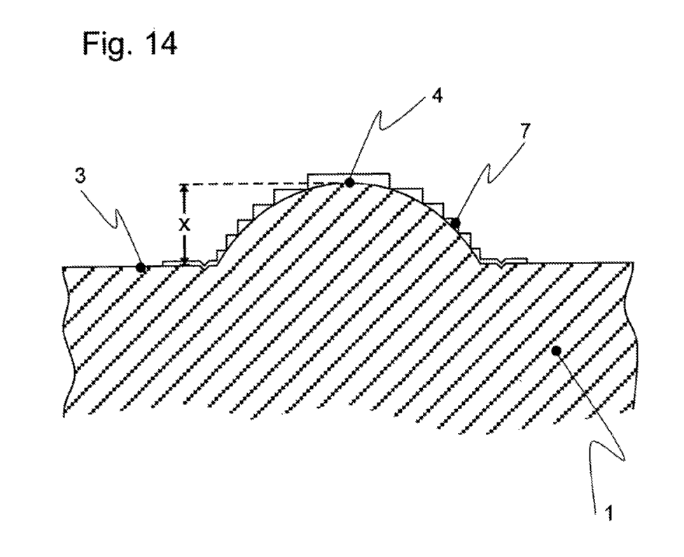

FIG. 14 shows a partial cross-sectional view of the first, but only exemplary, embodiment of an object to be structured that is illustrated in FIG. 1, which has a nonplanar surface at least in some regions, on which the structured additional body has been applied.

### DETAILED DESCRIPTION OF PREFERRED EMBODIMENTS

The detailed description which follows is made with reference to the accompanying drawings, which, however, are not true to scale. Specifically, the structure introduced into the object or applied to the object can be very much smaller in relation to the illustrated size of the object than is shown in the various figures.

For the sake of better understanding, the following definitions are given for some of the terms used in the present description and in the claims.

In accordance with the present description, a surface that is nonplanar comprises diffractive and/or refractive structures and/or free forms with preferably rotational symmetry or cylindrical symmetry and at least also all of the surfaces and shapes mentioned in DE 10 2004 38 727 A1. Furthermore, this surface can also have a stepped design.

The transfer of a structure, especially of a sacrificial layer that is arranged on a body, into the body comprises essentially the transfer of the lateral structure and the transfer of a similar vertical structure.

The structure to be transferred can be designed in the form of steps, which digitally represent only a step that is present and a step that is not present, as the zero or the one in the binary number range.

Moreover, nonbinary structures with different step heights can also be realized, for example, with two, three, or more than three step heights, in order to approximate, for example, regionally analog structures, such as Fresnel structures. In addition, the structures to be transferred can also have analog thickness or depth, i.e., thickness or depth that varies continuously with location, which also have discontinuities in certain sections, as is the case, for example, in analog Fresnel lenses.

In addition, the structure to be transferred can also be a certain surface texture. These can be moth-eye structures or surfaces with uniform, exactly determined roughness.

In this connection, the expression that a structure is similar is intended to mean that the structure in the surface shows essentially the same lateral dimensions other than deviations introduced by the transfer but can have a local depth that differs from the thickness of the sacrificial layer after the transfer, since the removal rate of the sacrificial layer can be different from the removal rate of the body into which the structure is transferred.

Consequently, as used in the context of the present description and the claims, a depth that is similar to the thickness means that although the surface shape of the sacrificial layer is locally transferred to the surface to be structured, which lies beneath the sacrificial layer, it is not necessarily transferred in its depth true to contour; in this connection, the term “similar” means that the structured surface will be locally deeper where the sacrificial layer is less thick, or where the sacrificial layer was deeper, this can be a depth proportional to the depth of the depression in the sacrificial layer if no saturation effects at all occur; however, even in the case of saturation effects or other effects, this can comprise a nonlinear dependence of the local depth or the local thickness of the sacrificial layer.

In this connection, deviations introduced by the transfer comprise essentially lateral effects caused by shadow casting, undercutting, or undesired scattering of light on masks or sacrificial layer boundaries.

For the sake of better understanding and to be able to claim at least parts of the disclosure of DE 10 2004 38 727 A1 in combination with the disclosed content of the present application, the entire content of DE 10 2004 38 727 A1 is also made the object of the present application by reference.

For the sake of better understanding, including especially better understanding of possible coatings, the entire content of DE 10 2006 059 775 A1 is also made the object of the present application by reference.

In the following description, reference is made to FIG. 1, which shows a partial cross-sectional view of a first, but only exemplary, embodiment of an object 1 to be structured, which has an at least regionally nonplanar surface 2 (in the present embodiment, this nonplanar region of the surface is convex).

On its surface that is to be structured 2, the base body has a planar region 3 and a nonplanar convex region 4.

Both the planar region 3 and the nonplanar convex region 4 or only one of the regions 3, 4 can be structured in a manner in accordance with the invention.

Otherwise, the base body 1 can be designed with essentially any desired shapes according to the given application. Thus, at least parts of the surface of the base body can be convexly shaped and in particular can be formed can be formed spherically, aspherically or freely.

In particular, the body structured according to the method of the invention can be a stamping or pressing mold with high surface precision.

In an especially preferred embodiment, the structured body is a stamping or pressing mold, especially a blank pressing mold, for producing an optical element, especially for producing an optical element that consists of glass or glass ceramic and that preferably has diffractive and/or refractive structures.

In this regard, reference is also made to the optical elements mentioned in DE 10 2004 38 727 A1, for which the base body can be used as a blank pressing mold, or which can each be produced by the structure-producing method of the invention.

In hybrid optical systems, a surface can be structured with the method of the invention, or several surfaces can also provided with their structure with this method.

In all of the cases mentioned above, the structured optical component can comprise Fresnel structures, diffractive optical structures and/or refractive optical structures.

In an alternative embodiment, the structured object or body can also comprise microfluidic structures, for example, systems of channels formed in the surface, with which experts in the field of microfluidics are familiar and which therefore do not need to be shown in the drawings.

Depending on the given application, the base body consists of a crystalline or ceramic material or has constituents that consist of these types of materials.

In this regard, the ceramic materials can comprise tungsten carbides, aluminum carbides, silicon carbides, titanium carbides, aluminum oxides, zirconium oxides, silicon nitrides, aluminum titanates and/or aluminum sintered materials and/or mixtures of these materials, especially as sintered materials, including especially powder metallurgy materials.

The crystalline materials preferably comprise silicon or sapphire.

In a method for producing a structured object, in order also to be able to structure a nonplanar surface of an object, so that it is possible, for example, to create optical systems, especially for use at relatively short wavelengths, such as blue light, at least two shaping surface machining processes are provided.

In a first surface machining process for shaping an object, the surface of the base body 1 can be machined in such a way, for example, that the base body 1 receives the planar region 3 and the nonplanar region 4.

In this first surface machining process, the surface 2 of the base body 1 can be machined over the entire surface or at least parts of the surface by means of grinding, polishing or lapping to obtain the convex bulging of the nonplanar region 4 illustrated in FIG. 1.

Depending on the material of the base body 1 to be structured, its surface 2, if, for example, it consists of glass or a glass ceramic, can also be shaped by stamping or pressing, including especially precision pressing.

The greatest height of the convex bulge of the nonplanar region produced by the first surface machining process and indicated with x in the drawings is typically greater by a factor of 10 than the magnitudes of the subsequently introduced structures, such as the depth of a step, which is formed, for example, in a second surface machining process.

In order to explain the structure formed in the second surface machining process, we first refer to FIG. 2, which shows a partial cross-sectional view of the same first embodiment of an object 1 illustrated in FIG. 1 with the structure introduced in accordance with the invention in the at least regionally nonplanar surface.

These finer structural magnitudes cannot typically be produced with extremely precise structure-producing methods, for example, lithographic methods, because the three-dimensionality of the convex elevation cannot be exposed with the required precision.

The base body 1 illustrated in FIG. 1, especially with the at least regionally nonplanar surface 2, is subsequently used to produce a structure, especially on the at least one nonplanar surface of the object, as is shown by way of example in FIG. 2.

In a first embodiment of the invention, the structuring of a sacrificial layer 5 is used for this purpose, which preferably can be structured more easily and/or precisely than the base body 1 itself, and subsequently the structure of the sacrificial layer is transferred to a surface 2 of the base body 1.

In this connection, the surface 2 is a surface of the base body 1, especially the nonplanar surface in the region 4 of the base body.

For this purpose, a sacrificial layer 5 is first applied to at least the region 4 of the surface that is subsequently to be structured, which can be carried out in various ways, depending on the material of the sacrificial layer.

In principle, the sacrificial layer illustrated in FIG. 3 can first be applied to the entire surface and then structured, as mentioned earlier, or the sacrificial layer 5 can be applied already structured.

In a further refinement, it is also possible to apply more than one sacrificial layer, for example, in order to achieve the required thicknesses of the sacrificial layer 5, and to this end all of the methods of application described above and below can be combined with one another.

If the sacrificial layer consists of metals and/or metallic alloys, especially nickel or a nickel-boron, nickel-phosphorus-boron, or nickel-phosphorus alloy, full-surface application of the sacrificial layer with subsequent structuring has proven effective.

In this case, it is advantageous if the sacrificial layer is structured by a removal process, especially by lithography, especially x-ray lithography, by laser ablation and/or by single crystal diamond machining, especially single crystal diamond turning.

Metals can often be structured much more precisely and easily than, for example, glasses or ceramics, and in this case, the precision that is possible here can be structurally transferred to the base body 1 by the prestructuring of the sacrificial layer.

In an alternative embodiment or, in the case of multilayer systems, an additional embodiment, the sacrificial layer comprises a dielectric, especially a resist, preferably a photoresist, which can then be structured by lithographic methods or, for the highest degree of precision, by mechanical methods, for example, single crystal diamond turning.

In another embodiment, the sacrificial layer consists of a polymerizable substance, especially a photopolymerizable substance, and can be structured by means of an application technique, especially laser polymerization, printing, especially three-dimensional printing.

A sacrificial layer can also consist of PMMA, which can be applied by spraying or in the furnace by heating preceded by casting.

In another embodiment, to increase the structural strength of the sacrificial layer, it contains nanoparticle constituents, especially nanoparticle metal constituents, plastic constituents and/or ceramic constituents. To adjust the material properties in a well-defined way, it is also possible to use mixtures with appropriate proportions of the various constituents.

In yet another embodiment, the sacrificial layer can also comprise a glass or a ceramic, especially one produced by a sol-gel process, such as zirconium oxide. After it has been applied, this dielectric can be structured with high precision by laser ablation.

After the sacrificial layer 5 has been applied over the entire surface, as illustrated in FIG. 3, and has been structured or has been applied already structured, an arrangement of the type shown in FIG. 4 is obtained, in which structures of the sacrificial layer are formed, which have a depth or thickness that varies from place to place in a well-defined way.

In a subsequent machining step, the structure of the sacrificial layer 5 is transferred to the base body 1, thereby structuring the surface 2 of the base body 1.

The transfer of the structure comprises the transfer of the lateral structure and the transfer of a similar vertical structure.

In a first embodiment, the structure is transferred by dry etching, especially by reactive ion etching, in which the ion beam preferably is directed to strike the sacrificial layer 5 essentially perpendicularly to the surface 2. In this regard, “essentially perpendicularly” to the surface 2 means the direction of the normal to the planar region 3.

Alternatively, the structure is transferred by wet-chemical etching, especially by directed etching along preferred crystal directions of a crystalline base body 1.

During the transfer of the structure of the sacrificial layer 5 to the surface 2, the thickness of the sacrificial layer is at least reduced or changed, thereby structuring the surface 2 of the base body 5.

In the process, the sacrificial layer can be completely consumed or it may be consumed only to a certain extent, with the remaining parts serving to shape the surface 2.

In an alternative embodiment or in a further modification of the method of the invention, a surface of at least one additional body is structured, which can be applied to the base body and which at first does not have to be applied on the base body.

To explain this variant of the method of the invention, we refer first to FIG. 9, which shows a cross-sectional view of a first embodiment of an additional body, which can be structured and applied to a base body in accordance with the invention. This additional body can be a film of a polymeric material that consists especially of polycarbonate, polyethylene and/or methyl methacrylate.

Furthermore, this additional body can also be produced by the structure-producing method described above, which results in a form of the type illustrated in FIG. 10.

In the case of a film, structure-producing methods, for example, lithographic methods, can be used with high precision without inadequate depth of definition resulting in inaccuracies, as would be the case with nonplanar objects, and the additional body can be subsequently applied to the surface 2 of the object 1, so that it becomes possible to transfer the precision of essentially two-dimensional shaping to three-dimensional and thus nonplanar objects.

In another embodiment, which is illustrated in FIGS. 11, 12 and 13, the structuring of an alternative additional body 7 can be carried out by means of a sacrificial layer 8, which can be applied as described above, so that the arrangement shown in FIG. 11 is obtained.

If the sacrificial layer is then structured or is applied already structured, the arrangement shown in FIG. 12 is obtained.

By transferring the structure of the sacrificial layer 8 to the additional body 7, the structured additional body 7 shown in FIG. 13 is obtained, which can be subsequently applied to the surface 2, as is shown in FIG. 14 for the state after the structured additional body 7 has been applied.

The additional body 7 can subsequently be used as a structure-producing element on the surface 2 of the object 1 or can be used again as a sacrificial layer for the object 1 for structuring its surface 2.

After the surface 2 of the object 1 has been structured, it is optionally coated with an antiadhesive coating, which for stamping or pressing molds, especially precision pressing molds, is helpful for removal from the mold after the stamping or pressing operation has been carried out.

This yields the arrangement illustrated in FIG. 6, which already represents a preferred embodiment for many applications, for example, for stamping and pressing applications.

The antiadhesive coating consists of a platinum-gold alloy, especially Pt₅Au, and/or alloys that contain platinum, iridium and rhodium, as well as other materials, such as are described, for example, in the incorporated document DE 10 2004 38 727 A1.

To obtain especially high contour sharpness, the antiadhesive coating 9 can first be applied and then structured as well.

This structuring leads to a layered structure, as shown in FIGS. 7 and 8.

In this regard, FIG. 7 shows a partial cross-sectional view of an embodiment of a structured object, in which at least part of the antiadhesive coating was structured, and FIG. 8 shows an enlarged segment of the embodiment illustrated in FIG. 7.

The antiadhesive coating is structured especially with the use of a sacrificial layer.

The invention is not limited to an antiadhesive coating 9, but rather one or more layers can be applied to the object 1 and structured, and thicker layers or deeper structures can be produced in this way.

The execution of the method of the invention is not limited to certain types of equipment or machines. However, to achieve especially high precision, it can be advantageous if an especially well-suited device is used for this purpose, which comprises a holding fixture for holding the base body and at least a first and a second device for structuring a surface, especially a surface of the base body 1.

To begin with, there is no need to provide drawings of the preferred embodiments of this device in the figures, but the first device for contouring or structuring can comprise a grinding spindle, a polishing spindle, a turning machine and/or a laser structuring device, especially a laser ablation device with an ablating laser and/or with an image setting laser, especially for photoresists.

To achieve the greatest possible machining precision, the second structuring device has a lithographic structuring device, especially a photolithographic structuring device, a galvanic structuring device, a single crystal diamond turning machine, a single crystal diamond milling machine, and/or a stamping device.

However, the holding fixture for holding the base body during the machining is well suited for holding the base body during the machining by the first structuring device and by the second structuring device, especially without new mounting of the base body and essentially without changed positioning, in order in this way to prevent the introduction of undesired defects by rechucking of the base body during its machining or at least to prevent additional, time-consuming processing steps.

Alternatively or additionally, the device described above includes an active optical positioning device.

1-38. (canceled)

39. A method for producing a structured object, especially for structuring a nonplanar surface of an object, which comprises
preparing a base body, especially one with at least one nonplanar surface,
producing a structure, especially on the one or more nonplanar surfaces of the object, which comprises
structuring of a sacrificial layer, which is effected with alignment especially relative to the nonplanar surface,
transferring the structure of the sacrificial layer to a surface,
wherein the surface is a surface of the base body, especially a nonplanar surface of the base body or
a surface of at least one additional body that can be applied to the base body,
wherein, when transferring the structure of the sacrificial layer to the surface, the thickness of the sacrificial layer is at least reduced or changed, thereby structuring the surface.

40. The method of claim 39, wherein the transfer of the structure comprises the transfer of the lateral structure and the transfer of a similar vertical structure, and/or in which the sacrificial layer is completely consumed.

41. The method of claim 39, wherein the structure is transferred be dry etching, especially reactive ion etching, or in which the structure is transferred by wet-chemical etching, especially directional etching along preferred crystal directions.

42. The method of claim 39, wherein the structured body is a stamping or pressing mold, and/or in which the structured body is a stamping or pressing mold, especially a blank pressing mold, for producing an optical element, especially for producing an optical element that consists of glass or glass ceramic and that preferably has diffractive and/or refractive structures.

43. The method of claim 39, wherein at least parts of the base body are structured by grinding, polishing or lapping its surface, and/or in which at least parts of the surface of the base body are formed spherically, aspherically or freely.

44. The method of claim 39, wherein the base body is comprised partly or completely of a material selected from the group consisting of ceramic materials and crystalline materials.

45. The method of claim 44, wherein the ceramic materials comprise tungsten carbides, aluminum carbides, silicon carbides, titanium carbides, aluminum oxides, zirconium oxides, silicon nitrides, aluminum titanates and/or aluminum sintered materials and/or mixtures of these materials, especially as sintered materials and especially as powder metallurgy materials, or in which the crystalline materials comprise silicon or sapphire.

46. The method of claim 39, wherein the base body is coated with an antiadhesive coating, or in which the base body is coated with an antiadhesive coating and in which the antiadhesive coating consists of a platinum-gold alloy, especially Pt5Au, and/or alloys that contain platinum, iridium and rhodium, or coatings that contain carbon, preferably coatings of the DLC type (diamond-like carbon type), or in which the base body is coated with an antiadhesive coating and in which the antiadhesive coating consists of a platinum-gold alloy, especially Pt₅Au, and/or alloys that contain platinum, iridium and rhodium, or coatings that contain carbon, preferably coatings of the DLC type (diamond-like carbon type) and in which the base body is structured, and then the antiadhesive coating is applied.

47. The method of claim 39, wherein the antiadhesive coating is applied and structured, especially with the use of a sacrificial layer, or is structured by single crystal diamond turning and/or single crystal diamond milling.

48. The method of claim 39, wherein the sacrificial layer comprises metals and/or metallic alloys, especially nickel or a nickel-boron, nickel-phosphorus-boron, or nickel-phosphorus alloy, and/or in which the sacrificial layer is structured by means of a removal technique, especially by lithography, especially x-ray lithography, laser ablation and/or single crystal diamond machining, especially single crystal diamond turning.

49. The method of claim 39, wherein the sacrificial layer comprises a dielectric, especially a resist, preferably a photoresist, a polymerizable substance, especially a photopolymerizable substance, and/or a ceramic, especially one produced by a sol-gel process (e.g., zirconium oxide), or in which the sacrificial layer comprises a dielectric, especially a resist, preferably a photoresist, a polymerizable substance, especially a photopolymerizable substance, and/or a ceramic, especially one produced by a sol-gel process (e.g., zirconium oxide) and in which the sacrificial layer is structured by an application technique, especially laser polymerization, printing, especially three-dimensional printing, preferably with nanoparticle constituents, especially with nanoparticle metal constituents, plastic constituents and/or ceramic constituents.

50. The method of claim 39, wherein the removal rate of the sacrificial layer is greater than or equal to the removal rate of the base body or the additional body, or in which the removal rate of the sacrificial layer is less than the removal rate of the base body or of the additional body.

51. The method of claim 39, wherein the additional body is a film, or in which the additional body is a film and in which the additional body is a film of polymeric material that consists especially of polycarbonate, PMMA, polyethylene, and/or methyl methacrylate.

52. A structured body produced by the method of claim 39.

53. The structured body of claim 52, comprising a structured optical component which comprises
Fresnel structures
diffractive optical structures, and/or refractive optical structures,
or which comprises microfluidic structures,
or which comprises a glass part or a crystal that is structured with a sacrificial layer.

54. A device for producing the structured body of claim 52, which comprises a holding fixture for holding the base body and at least a first and a second device for structuring a surface.

55. The device of claim 54, wherein the first structuring device comprises a grinding spindle, a polishing spindle, and/or a laser structuring device, especially a laser ablation device with an ablating laser and/or with an image setting laser, especially for photoresists, and/or in which the second structuring device comprises a lithographic structuring device, especially a photolithographic structuring device, a galvanic structuring device, and/or a stamping device, and/or in which the holding fixture for holding the base body is suited for holding the base body during the machining by the first structuring device and by the second structuring device, especially without new mounting of the base body and essentially without changed positioning.

56. The structured body of claim 52, comprising alignment marks and/or alignment areas on the base body that are located outside the optically active areas, or which comprises alignment marks and/or alignment areas on the base body that are located within the optically active areas.

57. An optical element with diffractive structures and/or refractive structures and/or moth-eye structures and/or well-defined roughness on nonplanar surfaces made of glass or glass ceramic produced with the method of claim 39.

58. A blank pressing mold with a diffractive structure on a nonplanar optically active surface for producing optical elements made of glass/glass ceramic, produced with the method of claim 39, especially a blank pressing mold which comprises alignment marks and/or alignment areas on the base body that are located outside the optically active areas.
